(19) United States
(12) Patent Application Publication
(10) Pub. No.: US 2026/0171118 A1
(43) Pub. Date: Jun. 18, 2026

(54) HIGH-BANDWIDTH MEMORY-BASED HOLOGRAPHY PROCESSING APPARATUS AND METHOD

(71) Applicant: ELECTRONICS AND TELECOMMUNICATIONS RESEARCH INSTITUTE, Daejeon (KR)

(72) Inventor: Won-Ok KWON, Sejong-si (KR)

(73) Assignee: ELECTRONICS AND TELECOMMUNICATIONS RESEARCH INSTITUTE, Daejeon (KR)

(21) Appl. No.: 19/407,096

(22) Filed: Dec. 3, 2025

(30) Foreign Application Priority Data
Dec. 18, 2024 (KR) 10-2024-0190198

(51) Int. Cl. G11B 7/0065; G11C 13/04

(52) U.S. Cl. CPC G11B 7/0065; G11C 13/042

(57) ABSTRACT

Disclosed herein are a High-Bandwidth Memory (HBM)-based holography processing apparatus and method. The HBM-based holography processing apparatus includes a holography row processing unit configured to receive image data and output row data of complex numbers obtained by performing a Fast Fourier Transform (FFT) on the image data, a HBM configured to store the output row data as data for each color and for each depth, and a holography column processing unit configured to read the stored row data using a column address and perform FFT processing on the read row data.

### CROSS REFERENCE TO RELATED APPLICATION

This application claims the benefit of Korean Patent Application No. 10-2024-0190198, filed Dec. 18, 2024, which is hereby incorporated by reference in its entirety into this application.

### BACKGROUND OF THE INVENTION

### 1. Technical Field

The following embodiments relate to a hardware structure for storage and processing by a real-time holography processor.

### 2. Description of the Related Art

A real-time holography processor performs a function of receiving two-dimensional (2D) RGB-Depth (RGBD) data as input and outputting real-time Computer-Generated Holography (CGH). That is, the real-time holography processor is a dedicated processor for performing mathematical calculations required for CGH generation.

In a data flow in this real-time holography processor, a two-dimensional (2D) Fast Fourier Transform (FFT) is the center of this calculation. In such 2D FFT calculation, row FFT is performed on an input image, after which column FFT is performed on the result of the row FFT.

The result of row FFT is large data that cannot be stored in an internal memory of System on Chip (SoC) or Field-Programmable Gate Array (FPGA). Generally, the result of row FFT is stored in an external memory such as Double Data Rate 4(DDR 4 ) memory having large memory capacity. DDR4 memory has an advantage of large capacity, but has disadvantages in that an access speed is much slower than that of the internal memory and it is difficult for a DDR4 controller to efficiently utilize multiple channels simultaneously.

Further, the result data of processing by the row processor of the real-time holography processor is a complex number composed of real number data and imaginary number data. Therefore, data of a single pixel is at least twice as large as that of a real number.

Furthermore, when layer data corresponding to RGB color channels and depth information of each channel is added, real-time processing of very large data is required.

### SUMMARY OF THE INVENTION

An embodiment is intended to perform data processing by a real-time holography processor at high speed.

In accordance with an aspect, there is provided a High-Bandwidth Memory (HBM)based holography processing apparatus includes a holography row processing unit configured to receive image data and output row data of complex numbers obtained by performing a Fast Fourier Transform (FFT) on the image data, a HBM configured to store the output row data as data for each color and for each depth, and a holography column processing unit configured to read the stored row data using a column address and perform FFT processing on the read row data.

Here, the holography row processing unit may include a color channel separation unit configured to separate data for each color from the image data, a depth processing unit configured to obtain data for each of depths from the image data, a preprocessing unit configured to preprocess the color data and the depth data on a row basis, and a row Fast Fourier Transform (FFT) processing unit configured to perform an FFT on the preprocessed color data and depth data.

Here, the HBM may store row FFT data for each channel, wherein, when a size of stored data for each color or depths is larger than a channel size, at least two channels may be allocated to each color or depth.

Here, the HBM may be configured such that writing may be performed in one of at least two channels for each color or depth while reading is performed in a remaining channel.

Here, the holography column processing unit may include 2ⁿ column processing units.

Here, the holography row processing unit may write row data to one of at least two channels for each color or depth, and may then determine whether the remaining channel is available, and may write data to the remaining channel when it is determined that the remaining channel is available.

Here, when it is determined that the remaining channel is unavailable, the holography row processing unit may wait until reading of column data is completed, and may then write row data to the remaining channel if the reading of the column data is completed.

Here, the holography column processing unit may complete reading of column data from one of at least two channels for each color or depth, and thereafter immediately perform reading from the remaining channel.

In accordance with another aspect, there is provided a High-Bandwidth Memory (HBM)-based holography processing method, including receiving image data and then outputting row data of complex numbers obtained by performing an FFT on the image data, writing the output row data to a HBM for each color and each depth, reading the row data stored in the HBM using a column address, and performing FFT processing on the read column data.

Here, writing the output row data may include separating data for each color from the image data, obtaining data for each depth from the image data, preprocessing the color data and the depth data on a row basis, and performing an FFT on the preprocessed color data and depth data.

Here, the HBM may be configured to store row FFT data for each channel, and when a size of stored data for each color or depth is larger than a channel size, allocate at least two channels for each color or depth.

Here, the HBM may be configured such that writing may be performed in one of at least two channels for each color or depth while reading is performed in a remaining channel.

Here, the holography column processing unit may include 2ⁿ column processing units.

Here, the writing the output row data may include writing row data to one of at least two channels for each color or each depth, determining whether the remaining channel is available, and when it is determined that the remaining channel is available, writing the row data to the remaining channel.

Here, writing the output row data may further include, when it is determined that the remaining channel is unavailable, waiting for reading of column data to be completed, and writing the row data to the remaining channel when reading of the column data is completed.

Here, reading the row data may include completing reading of column data from one of at least two channels for each color or depth, and thereafter immediately performing reading from the remaining channel.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a schematic block configuration diagram of a High-Bandwidth Memory (HBM)-based holography processing apparatus;

FIG. 2 is a diagram illustrating an example of the internal structure of a HBM according to an embodiment;

FIG. 3 is a diagram illustrating an example of reading from a HBM by a holography column processing unit according to an embodiment;

FIG. 4 is a diagram illustrating the internal structure of a holography column processing unit according to an embodiment;

FIG. 5 is a flowchart for explaining the step of writing to a HBM according to an embodiment; and

FIG. 6 is a flowchart for explaining the step of reading from a HBM according to an embodiment.

### DESCRIPTION OF THE PREFERRED EMBODIMENTS

Advantages and features of the present disclosure and methods for achieving the same will be clarified with reference to embodiments described later in detail together with the accompanying drawings. However, the present disclosure is capable of being implemented in various forms, and is not limited to the embodiments described later, and these embodiments are provided so that this disclosure will be thorough and complete and will fully convey the scope of the present disclosure to those skilled in the art. The present disclosure should be defined by the scope of the accompanying claims. The same reference numerals are used to designate the same components throughout the specification.

It will be understood that, although the terms “first” and “second” may be used herein to describe various components, these components are not limited by these terms. These terms are only used to distinguish one component from another component. Therefore, it will be apparent that a first component, which will be described below, may alternatively be a second component without departing from the technical spirit of the present disclosure.

The terms used in the present specification are merely used to describe embodiments, and are not intended to limit the present disclosure. In the present specification, a singular expression includes the plural sense unless a description to the contrary is specifically made in context. It should be understood that the term “comprises” or “comprising” used in the specification implies that a described component or step is not intended to exclude the possibility that one or more other components or steps will be present or added.

Unless differently defined, all terms used in the present specification can be construed as having the same meanings as terms generally understood by those skilled in the art to which the present disclosure pertains. Further, terms defined in generally used dictionaries are not to be interpreted as having ideal or excessively formal meanings unless they are definitely defined in the present specification.

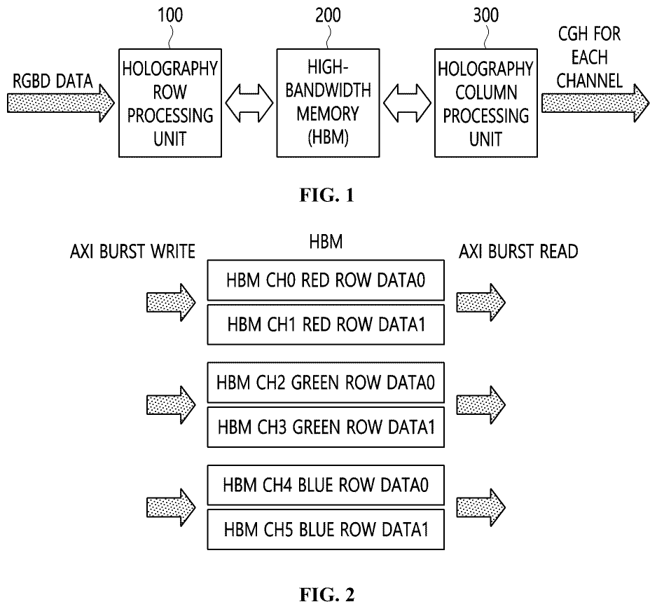

FIG. 1 is a schematic block configuration diagram of a High-Bandwidth Memory (HBM)-based holography processing apparatus.

Referring to FIG. 1, the High-Bandwidth Memory (HBM)-based holography processing apparatus according to the embodiment may include a holography row processing unit 100, a HBM 200, and a holography column processing unit 300.

The holography row processing unit 100 may receive image data and output row data of complex numbers obtained by performing a Fast Fourier Transform (FFT) on the image data.

In detail, the holography row processing unit 100 may include a color channel separation unit which separates data for each color from the image data, a depth processing unit which obtains data for each of depths from the image data, a preprocessing unit which preprocesses the color data and the depth data on a row basis, and a row Fast Fourier Transform (FFT) processing unit which performs an FFT on the preprocessed color data and depth data.

The HBM 200 may store the output row data as data for each color and data for each depth.

The HBM 200 provides a high-bandwidth interface of 1024 bits (HBM3 enhanced: HBM3E) by vertically stacking Dynamic Random Access Memories (DRAMs), thus providing high bandwidth.

Here, the HBM 200 includes several tens of channels, each of which includes two Pseudo Channels (PCs). Further, in all of the pseudo channels, HBM memory controllers may be independently present.

In addition, the HBM 200 is a memory most suitable for a holography processor which performs simultaneous parallel processing of RGB color channels and processes a high-speed 2D FFT.

The row data in the HBM 200 is stored at a very high speed through writing to consecutive addresses (i.e., burst write).

The holography column processing unit 300 may read the row data stored in the HBM 200 using a column address, and may perform FFT processing on the read data.

Here, the holography column processing unit 300 reads the stored row data using the column address, and then performs operations such as focus information processing, column FFT, and conversion into complex data.

In this case, the operation of reading column data corresponds to reading from non-consecutive addresses (i.e., random read), and is then performed much more slowly than the write operation (i.e., burst write) by the holography row processing unit 100.

Therefore, in the HBM-based holography processing apparatus (hereinafter also referred to as ‘real-time holography processor’), it is very important to design the operating speed of the holography column processing unit 300 to be similar to that of the holography row processing unit 100.

FIG. 2 is a diagram illustrating an example of the internal structure of a HBM according to an embodiment.

Referring to FIG. 2, the HBM 200 may store row FFT data for each channel because the HBM 200 includes multiple channels.

Here, when the size of stored data for each color or depth is larger than the size of the corresponding channel, at least two channels may be allocated to each color or depth.

Therefore, writing may be performed in one of at least two channels for each color or depth while reading is performed in another channel through the HBM 200.

This is referred to as a double buffering method, in which, during hologram data processing, two storage spaces for each color are provided, and then a row write operation may be performed in one channel while a column read operation is being performed in another channel.

For example, as illustrated in FIG. 2, an operation of writing red row FFT data in channel ch1 may be performed at the same time that an operation of reading red column FFT data is performed in channel ch0.

That is, the holography row processing unit 100 according to the embodiment may write row data to one of at least two channels for each color or depth, and may then determine whether another channel is available. When it is determined that the other channel is available, the holography row processing unit 100 may write data to the other channel.

In this case, when it is determined that the other channel is unavailable, the holography row processing unit 100 may wait until reading of column data is completed, and may then write row data to the other channel if the reading of the column data is completed.

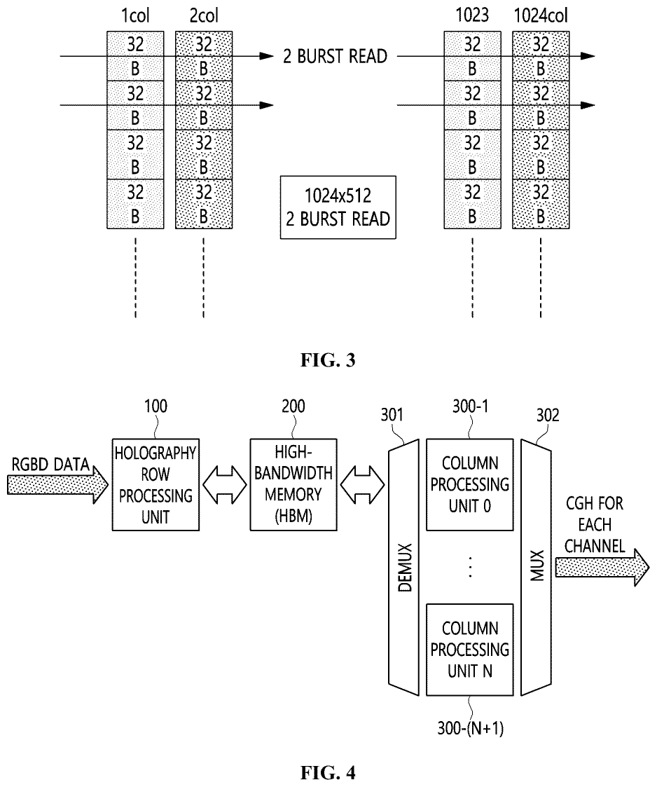

FIG. 3 is a diagram illustrating an example of reading from a HBM by a holography column processing unit according to an embodiment, and FIG. 4 is a configuration diagram illustrating the internal structure of the holography column processing unit according to an embodiment.

Referring to FIGS. 3 and 4, the holography column processing unit 300 may include a Demultiplexer (DEMUX) 301, 2ⁿ column processing units 300-1, . . . , 300-(N+1), and a Multiplexer (MUX) 302.

### That Is, in Order to Compensate for a Low Column Read Speed Through the 2ⁿ Column

processing units 300-1, . . . , 300-(N+1), hardware may be extended to simultaneously process columns such as 2, 4, or 8 columns.

That is, after a 2-burst read operation is performed, first 32B complex data is processed by column processing unit #0 (i.e., column processing block #0), and second 32B complex data is processed by column processing block #1 that is additionally extended.

In the case of a 1024×1024 pixel image, the processing speed may be improved while a 2-burst read operation is repeatedly performed 1024×512 times.

Here, the holography column processing unit 300 may complete reading of column data from one of at least two channels for each color or depth, and thereafter immediately perform reading from another channel.

Meanwhile, an HBM-based holography processing method according to an embodiment may include the step of receiving image data and then outputting row data of complex numbers obtained by performing an FFT on the image data, the step of writing the output row data to a HBM for each color and each depth, the step of reading the row data stored in the HBM using a column address, and the step of performing FFT processing on the read column data.

Here, the outputting step may include the step of separating data for each color from the image data, the step of obtaining data for each depth from the image data, the step of preprocessing the color data and the depth data on a row basis, and the step of performing an FFT on the preprocessed color data and depth data.

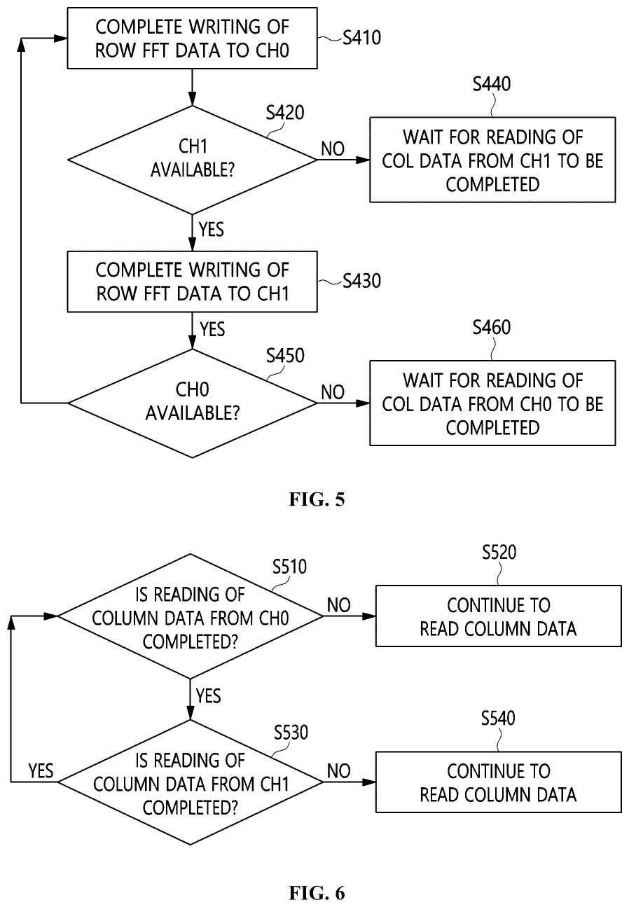

FIG. 5 is a flowchart for explaining the step of writing to a HBM according to an embodiment.

Referring to FIG. 5, the writing step according to the embodiment may include step S410 of writing row data to one of at least two channels for each color or each depth, step S420 of determining whether another channel is available, and step S430 of, when it is determined that the other channel is available, writing the row data to the other channel.

Here, the writing step may further include step S440 of, when it is determined that the other channel is unavailable, waiting until reading of column data is completed. After that, the writing step proceed to step S430 of writing the row data to the other channel when reading of the column data is completed. Then, in the same manner as in steps S420 and S430, the availability of the channel written to in step S410 is checked in step S450, and waiting is performed in step S460 if necessary, followed by proceeding to step S410.

FIG. 6 is a flowchart for explaining the step of reading from a HBM according to an embodiment.

Referring to FIG. 6, the reading step according to the embodiment may include step S510 of completing reading of column data from one of at least two channels for each color or depth, and thereafter immediately performing reading from another channel at step S530.

That is, the reading step is always performed more slowly than the writing step. However, the case where column processing is performed faster than row processing results in a waste of hardware resources, and the optimal design method is to design column processing hardware to operate at a speed nearly equal to, but slightly slower than that of row processing hardware. Therefore, column memory control is performed such that, when reading of data from one channel is terminated, a read operation from another channel is performed without needing to check whether the other channel is available, and this process is repeatedly performed.

As described above, in the embodiment, methods for effectively storing and processing holography 2D FFT data in the real-time holography processor using the HBM are handled.

That is, in the case of row FFT data stored in the HBM, multiple pieces of channel and depth data may be processed fast through a double buffering technique, and in the case of column data processing, multiple pieces of column data are processed using parallelized column processing cores, thus improving the speed of cores based on row processing.

Therefore, according to embodiments, a cgh processor that is capable of processing a high frame rate in real time can be developed.

According to embodiments, data processing by a real-time holography processor can be performed at high speed.

Although the embodiment of the present invention has been disclosed, those skilled in the art will appreciate that the present invention can be implemented as other concrete forms, without departing from the scope and spirit of the invention as disclosed in the accompanying claims. Therefore, it should be understood that the exemplary embodiment is only for illustrative purpose and do not limit the scope of the present disclosure.

What is claimed is:

1. A High-Bandwidth Memory (HBM)-based holography processing apparatus, comprising:
a holography row processing unit configured to receive image data and output row data of complex numbers obtained by performing a Fast Fourier Transform (FFT) on the image data;
a HBM configured to store the output row data as data for each color and for each depth; and
a holography column processing unit configured to read the stored row data using a column address and perform FFT processing on the read row data,
wherein the HBM is configured to allow writing to one of at least two channels for each color or depth while reading from a remaining channel.

2. The HBM-based holography processing apparatus of claim 1, wherein the HBM is configured to:
store row FFT data for each channel, and
when a size of stored data for each color or depth is larger than a channel size, allocate at least two channels for each of the colors or depths.

3. The HBM-based holography processing apparatus of claim 2, wherein the holography row processing unit is configured to write row data to one of the at least two channels for each color or depth, and then determines whether a remaining channel is available, and writes the row data to the remaining channel when it is determined that the remaining channel is available.

4. The HBM-based holography processing apparatus of claim 2, wherein the holography row processing unit is configured to, when it is determined that the remaining channel is unavailable, wait until reading of column data is completed, and then write the row data to the remaining channel when reading of the column data is completed.

5. The HBM-based holography processing apparatus of claim 2, wherein the holography column processing unit is configured to, after reading of column data from one of the at least two channels is completed for each color or depth, immediately perform reading from the remaining channel.

6. A HBM-based holography processing method, comprising:
receiving image data and outputting row data of complex numbers obtained by performing a Fast Fourier Transform (FFT) on the image data;
writing the output row data to a HBM, as data for each color and for each depth;
reading the row data stored in the HBM using a column address; and
performing FFT processing on the read column data,
wherein the HBM is configured to allow writing to one of at least two channels for each color or depth while reading from a remaining channel.

7. The HBM-based holography processing method of claim 6, wherein the HBM is configured to:
store row FFT data for each channel, and
when a size of stored data for each color or depth is larger than a channel size, allocate at least two channels for each color or depth.

8. The HBM-based holography processing method of claim 6, wherein writing the output row data comprises:
writing the row data to one of the at least two channels for each color or depth;
determining whether the remaining channel is available; and
writing the row data to the remaining channel when it is determined that the remaining channel is available.

9. The HBM-based holography processing method of claim 8, wherein writing the output row data further comprises:
when it is determined that the remaining channel is unavailable, waiting until reading of column data is completed; and
writing the row data to the remaining channel when reading of the column data is completed.

10. The HBM-based holography processing method of claim 6, wherein reading the row data comprises:
after reading of column data from one of the at least two channels is completed for each color or depth, immediately performing reading from the remaining channel.
